(19) United States
(12) Patent Application Publication
(10) Pub. No.: US 2015/0060619 A1
(43) Pub. Date: Mar. 5, 2015

(54) SOLAR MODULE BRACKET

(71) Applicant: K2 SYSTEMS GMBH, Renniugen (DE)

(72) Inventors: Kurt Krannich, Weil der Stadt/Hausen (DE); Veit Schütz, Stuttgart (DE)

(21) Appl. No.: 14/385,859

(22) PCT Filed: Oct. 19, 2012
(86) PCT No.: PCT/EP2012/004401

§ 371 Date: Sep. 17, 2014

(30) Foreign Application Priority Data
Mar. 19, 2012 (DE) 10 2012 005 320.7
Jun. 12, 2012 (DE) 10 2012 011 969.0

(51) Int. Cl. F24J 2/52; H01L 31/042; H02S 20/23; H01L 31/02

(52) U.S. Cl. CPC F24J 2/5245; H01L 31/02; H01L 31/042; H02S 20/23
USPC 248/237

(57) ABSTRACT

The present disclosure relates to a solar module bracket (1) having a base support (2), more particularly a base support capable of being mounted on a roof, and a yoke support (3) for holding a module support rail (9), wherein the yoke support (3) has a fastening area (4) which is separably connected to the base support (2). It is proposed that the fastening area (4) is formed from a yoke section (19) of said yoke support (3), comprising a plurality of arms (15, 16), wherein each arm (15, 16) of the yoke section (19) is separably connected to the base support (2).

The invention relates to a solar module bracket having a base support which is fastenable in particular on a roof and a yoke support for holding a module support rail, wherein the yoke support comprises a fastening region which is releasably connected to the base support.

A solar module bracket of this type is known from DE 102 13 902 A1. It serves for the purpose of fastening solar modules on a roof of a building. To this end, the base support is fastened on a roof structure, for example on a rafter. The yoke support, which is releasably fastened on the base support, as a result of its curved form, engages around a roof covering, for example a roof tile, such that its free end region lies above the roof covering and is able to hold a module support rail there on which at least one solar module is fastened. As the solar module is exposed to the weather, it is, for example, covered with a load of snow in winter or is acted upon with the force of the wind in a storm. On account of its structure, the known solar module bracket is less suitable to withstand the changes in the different external forces sufficiently over a longer period.

Consequently, the object underlying the invention is to provide a solar module bracket which comprises a simple structure, is cost-efficient to produce and has a high degree of stability. In particular, over and above this, it should be suitable to compensate for changes in length caused by temperature fluctuations.

Said object is achieved according to the invention in that the fastening region is formed by a yoke portion of the yoke support which comprises several arms, wherein each arm of the yoke portion is releasably connected to the base support. According to the invention, a load which is to be diverted from the yoke support to the base support is consequently discharged via several arms such that each arm only has to accept a part force, thereby producing a very stable structure for the solar module bracket. In addition, several arms prevent the yoke support from tilting in an inadmissible manner as, on account of the arms that are located spaced apart from one another, support points that lie spaced apart from one another are created.

According to a further development of the invention, it is provided that the fastening region is associated with a first end region of the yoke support. The fastening of the yoke support on the base support is consequently effected in said first end region.

In addition, it is advantageous when the yoke support comprises a yoke center region which merges integrally into a branching region which, in turn, merges integrally into the arms. The yoke center region is developed in an arcuate manner, in particular in an approximately U-shaped manner, in order to engage around the roof covering, for example the named roof tile. Said U-shaped yoke center region merges integrally into the named branching region which forms the common root for the arms which proceed from there and are integrally connected to the branching region. All in all, consequently, there is integrality between the yoke center region and the arms.

According to a preferred embodiment of the invention, two arms (precisely two arms) are provided, which results in the branching region being developed as a V-shaped branching region.

In addition, it is advantageous when the longitudinal extensions of the arms enclose at least in portions an acute angle. Proceeding from the branching region, the arms realize the named acute angle with respect to one another, which results in the free ends of the arms being located at a spacing from one another and consequently spanning a large and secure standing area.

A further development of the invention provides that at least one of the arms is an angled arm. As a result of the angled arm, the arm portion thereof which is associated with the free end is able to assume a parallel position with respect to the other non-angled arm such that the fastening of the two arms on the base support can be realized in the same manner.

A further development of the invention provides that the free ends of the arms are connected to the base support by means of slot nut connections. It is provided, in particular, that the free ends of the arms comprise slot nuts and that the base support is provided with receiving grooves, in particular C-profile grooves. By simply pushing the slot nuts into the C-profile grooves, the yoke support can consequently be releasably held on the base support.

In particular, the base support is realized as a base plate such that there is a flat but sufficiently large structure with regard to area. As an alternative to this, in a preferred manner the base support comprises a base plate on which are arranged, for example, means which serve for connecting the arms to the base support.

A further development of the invention provides that the base support comprises at least one fastening hole which lies between the arms. In order to fasten the base support for example to the mentioned roof of the building, a fastening element, in particular a stainless steel wood screw, is inserted into the fastening hole and then, for example, screwed into the rafters. As the mentioned fastening hole lies between the arms, a high degree of stability is ensured as the fastening element lies close to the arms, namely even between the arms. In a preferred manner, several fastening holes are provided in the base support in order to be able to insert further fastening elements, it being possible for said further fastening holes also to be located at least in part between the arms and/or also outside the region of the base support that is located between the arms in order to make it possible to vary the fastening or screwing position of the base plate on, for example, a rafter, a purlin, a batten and so on. According to an alternative preferred embodiment, at least one fastening hole lies outside a region of the base support which lies between the arms in order to ensure good force distribution and/or simple assembly of the base support.

A further development of the invention provides that the yoke support spans a yoke center plane, wherein the arms lie in the yoke center plane. On account of its curved form, in particular U-shaped form, the yoke support spans the mentioned yoke center plane. The arms also lie in the same plane. This means that all or both arms lie in said (same) plane and there is for instance no structure where one arm lies to the right of the named yoke center plane and the other arm lies to the left of said plane.

It is advantageous when the yoke support comprises a yoke width which is constant or approximately constant over the entire longitudinal development of the yoke support. Accordingly, the yoke center region, the branching region and the arms are realized with the same width or approximately the same width. It is provided, in particular, that the yoke support is produced as an extruded component which, after extrusion, is simply cut into “disks”, the disk thickness corresponding to the mentioned yoke width.

It is advantageous when the yoke support comprises a module holding region which forms a second end region of the yoke support. The module support rail is fastened in said second end region. A clamping holder serves for the fastening—according to a further development of the invention. This means that the module support rail is held on the yoke support as a result of clamping.

It is advantageous when at least one of the arms extends in a straight line and is oriented in a perpendicular manner with respect to the plane of the base plate. It is provided in this case in a preferred manner that the angled arm comprises an arm portion which is oriented in a perpendicular manner with respect to the plane of the base plate. In particular, it can be provided in this case that the arm portion is connected to the base support by means of one of the slot nut connections. The above development produces very stable fastening of the yoke support on the base support.

According to a further development of the invention, it is provided that the yoke center region comprises a bending to which the branching region connects in a direct manner. As a result, a flat structure of the solar module bracket is achieved in order to be able to engage under the mentioned roofing tile.

Finally, it is advantageous when the slot nut connections are realized as displacing connections. This means that they are not secured—for example by way of clamping means—but that the slot nuts are able to move in the receiving grooves, in particular C-profile grooves, in the longitudinal direction of the groove in order to be able to compensate for thermal expansion in this manner. This prevents the build-up of material stresses.

Several solar module brackets are preferably always provided in order to hold a module support rail, a stop device which prevents the yoke support of said solar module bracket being able to slip out of the associated base support then being provided at least in the case of one of the solar module brackets.

According to a further development of the invention, it is provided that the slot nut connections comprise in each case a slot nut which is provided on the free end of the respective arm and at least one receiving means, in particular receiving groove, for the slot nut, which is provided on the base support. In particular, the receiving groove comprises a longitudinal extension along which the slot nut is arranged so as to be pushable into the receiving groove and displaceable in the receiving groove. A tongue and groove connection between the yoke support and the base support is created therefore as a result of the slot nut connections. In this case, this is a simple and flexible connection as the slot nuts can be displaced into the receiving grooves for adaptation to local conditions in order to adjust a desired positioning of the yoke bracket relative to the base support. In addition, thermal stresses are avoided as a result of said displaceable connection.

It is preferably provided that the slot nut is realized as an L-slot nut or a T-slot nut. An L-slot nut is to be understood as an L-shaped slot nut, i.e. the free end of the associated arm is realized “in a kinked manner” such that, all in all, the end region of the arm comprises an L-form. In a corresponding manner, a T-slot nut is to be understood as a T-shaped slot nut, i.e. the end region of the associated arm comprises a T-form.

It is advantageous when the receiving groove is realized as a push-in receiving groove or a hook-in receiving groove. A push-in receiving groove is to be understood as a receiving groove into which the associated slot nut can be inserted by pushing it in the direction of the longitudinal extension of the receiving groove. Due to the dimensioning of the longitudinal opening and of the slot nut, it is not possible to insert the slot nut into the push-in receiving groove through its longitudinal opening. In particular, the width of the longitudinal opening is smaller than the width of the slot nut. A hook-in receiving groove is to be understood as a receiving groove, the longitudinal opening of which is dimensioned in such a manner that it is possible to insert the associated slot nut into the receiving groove through the longitudinal opening thereof, as a result of which the assembly is able to be made easier. In particular, the width of the longitudinal opening is greater than the width of the slot nut. In order to achieve a tongue and groove system between the slot nut and the hook-in receiving groove during assembly, it is first of all necessary to insert the slot nut into the longitudinal opening of the receiving groove. This is effected transversely with respect to the longitudinal extension of the receiving groove. The slot nut then has to be moved in the receiving groove. The moving is effected transversely with respect to the insertion movement and transversely with respect to the longitudinal extension of the receiving groove. As a result, a tongue and groove system between the slot nut and the hook-in receiving groove is ensured overall. The yoke support is therefore connected to the base support by hooking the slot nut into the hook-in receiving groove or is separated from said base support by unhooking it. Naturally, the slot nut can also be inserted into the hook-in receiving groove as a result of pushing it in (in the direction of the longitudinal extension of the hook-in receiving groove) or can be removed therefrom as a result of pushing it out.

According to an advantageous further development of the invention, it is provided that several receiving grooves, which are at different height intervals from the plane of the base plate, are provided on the base support for each groove. Height adjustability of the yoke support relative to the base support and in particular to the roof on which the base support is fastened is achieved as a result of the several receiving grooves per slot nut. Consequently, the solar module bracket can be adapted to the specific conditions of the roof in order to ensure always that the roof covering is able to be engaged around by the yoke support. The solar module bracket can also be used in a versatile manner as a result of said realization, in particular on different types of roof structures and roof coverings.

A further development of the invention provides that the several receiving grooves are provided arranged one above another on a holder which is provided on the base plate. The receiving grooves are realized for the at least two slot nuts as a result of the holder and/or the holder in combination with the base plate. The base support is preferably realized integrally with the base plate and the holder, in particular as an extruded component.

According to a preferred further development of the invention, it is provided that the holder comprises two longitudinal walls, which project away from the base plate in a perpendicular manner and are parallel to one another, with in each case several cross walls, wherein the receiving grooves are realized between the base plate and two of the cross walls as well as between the further cross walls. In a preferred manner the cross walls project away from each of the longitudinal walls in a perpendicular manner such that the cross walls extend parallel to the base plate and parallel to one another. The distance between the base plate and the adjacent cross walls as well as the distance between adjacent cross walls is preferably the same size such that identical receiving grooves are realized.

It is provided in particular that a support strut, which is associated with the base support, for the arms is arranged between the longitudinal walls. In an advantageous manner, the arms are guided along the support strut when the slot nuts are pushed into the receiving grooves, as a result of which the slot nuts are prevented from canting in the receiving grooves. The support strut preferably defines the receiving grooves. In a preferred manner, the support strut is preferably also produced during the extrusion of the base support.

In particular, at least one clamping safety device is provided for effectively securing the relative position of the yoke support and the base support with respect to one another in particular in the direction of the longitudinal extensions of the receiving grooves. Therefore, the yoke support is held fixedly on the base support and the slot nuts are prevented from being pushed into the receiving grooves by means of the clamping safety device. The clamping safety device also prevents the slot nuts from slipping out of the receiving grooves or—where the receiving groove is realized as a hook-in receiving groove—from being able to unhook by releasing the tongue and groove system.

According to a preferred further development of the invention, it is provided that the clamping safety device comprises at least one clamping screw which is screwed into a threaded bore of the base support and is supported on the yoke support and/or at least one clamping screw which is screwed into a threaded bore of the yoke support and is supported on the base support. A clamping force, which acts onto the yoke support transversely with respect to the push-in direction (or longitudinal extension of the receiving grooves) and/or insertion direction (with reference to the hook-in receiving groove), is generated as a result of the clamping screw, as a result of which said yoke support is secured relative to the base support.

In addition, according to a further development of the invention, it is provided that the clamping safety device comprises at least one locating screw which, by way of its thread, is screwed into a screw channel which is realized between an arm and a longitudinal web of the base support which proceeds from the base plate and defines at least one of the receiving grooves in regions. The receiving groove is preferably a hook-in receiving groove. The locating screw then serves for the purpose of locating the slot nuts in the receiving grooves in their tongue and groove position. To this end, as a result of the diameter of the locating screw a force is exerted onto at least one of the arms such that the slot nuts are urged into their tongue and groove position. The locating screw prevents, on the one hand, the slot nuts being displaced along the longitudinal extension of the receiving grooves and, on the other hand, the tongue and groove system being released and the slot nuts slipping out of the longitudinal opening of the respective receiving groove.

The screw channel can be formed by a toothing provided on the longitudinal web of the base support and a toothing provided on the arm such that overall there is a type of internal thread for the locating screw. As an alternative to this, it can also be a self-tapping locating screw which generates a threaded toothing in the screw channel itself.

The drawings illustrate the invention by way of an exemplary embodiment, in which:

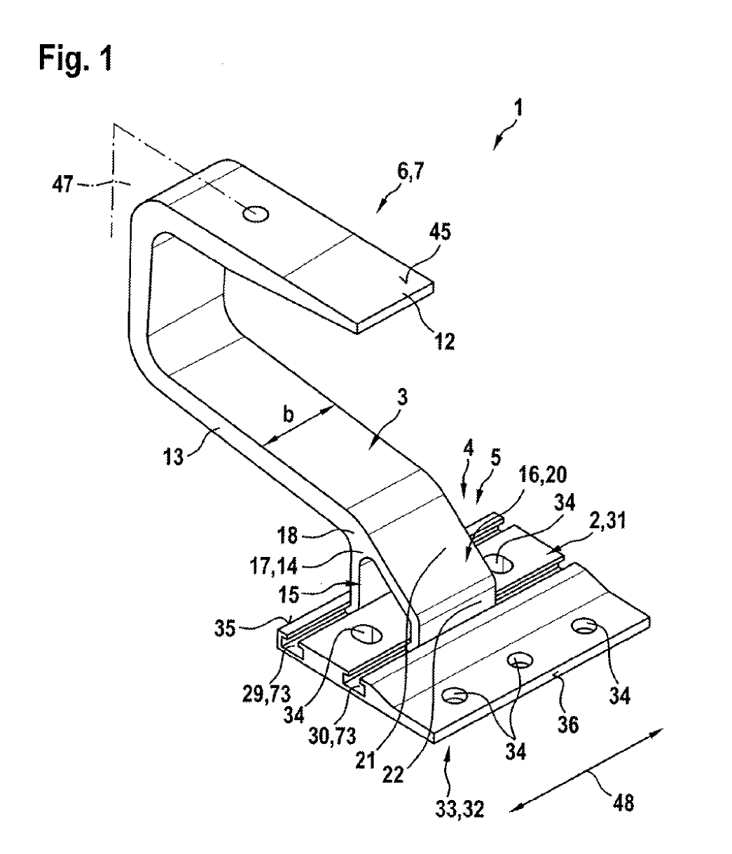

FIG. 1 shows a perspective representation of a solar module bracket according to a first exemplary embodiment,

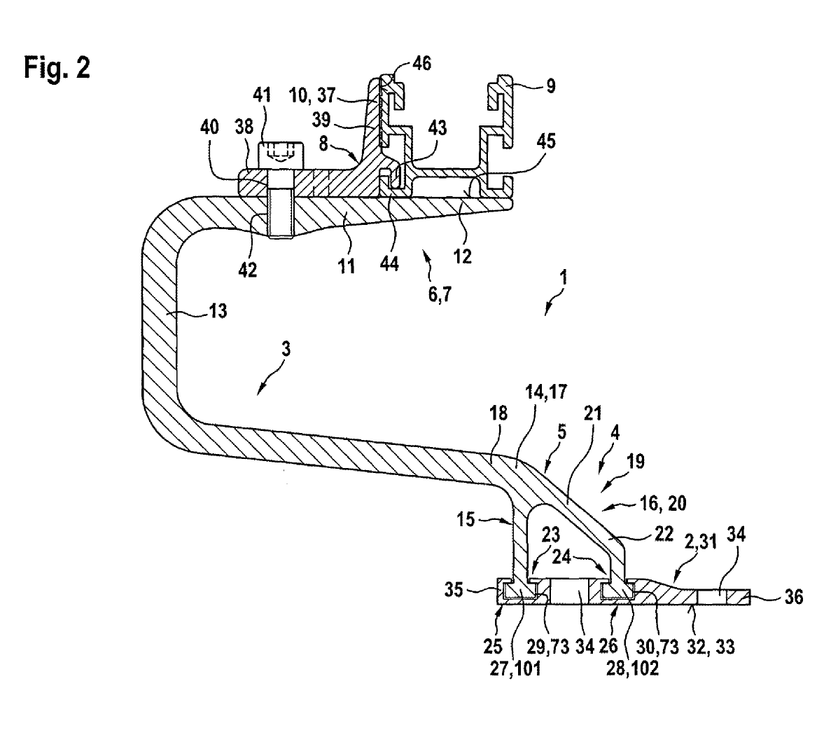

FIG. 2 shows a cross section through the solar module bracket of FIG. 1 with a module support rail,

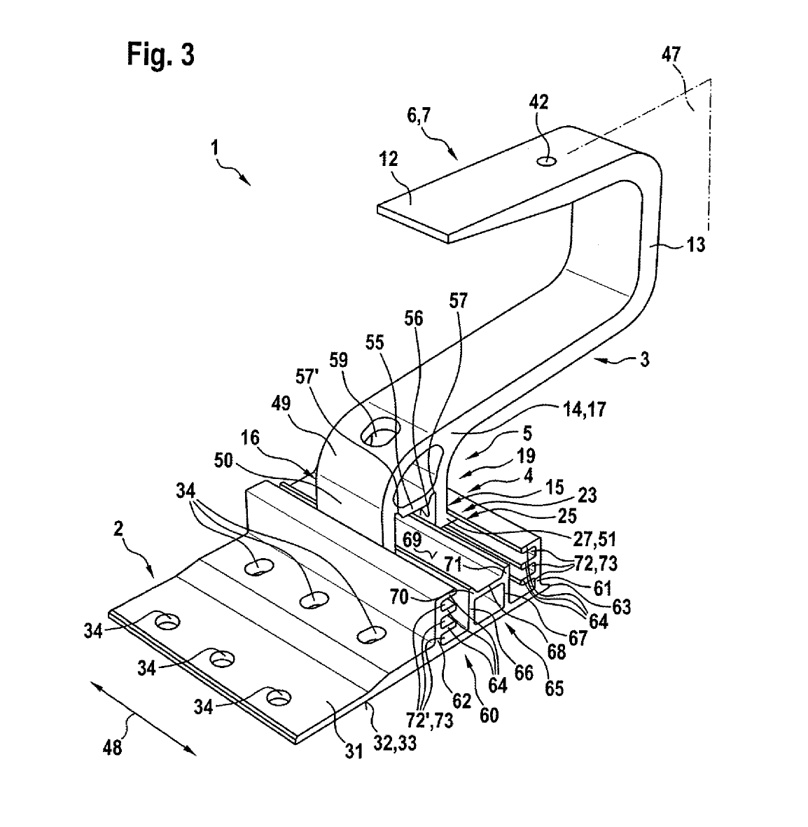

FIG. 3 shows a perspective representation of a solar module bracket according to a second exemplary embodiment in a first position,

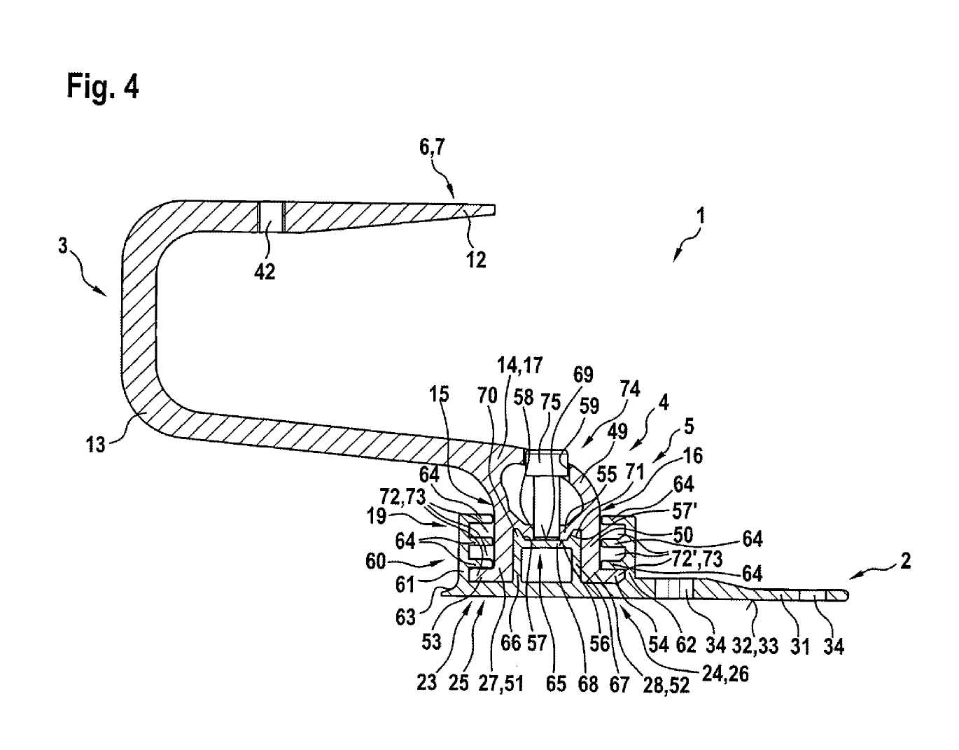

FIG. 4 shows a cross section through the solar module bracket of FIG. 3 in a second position,

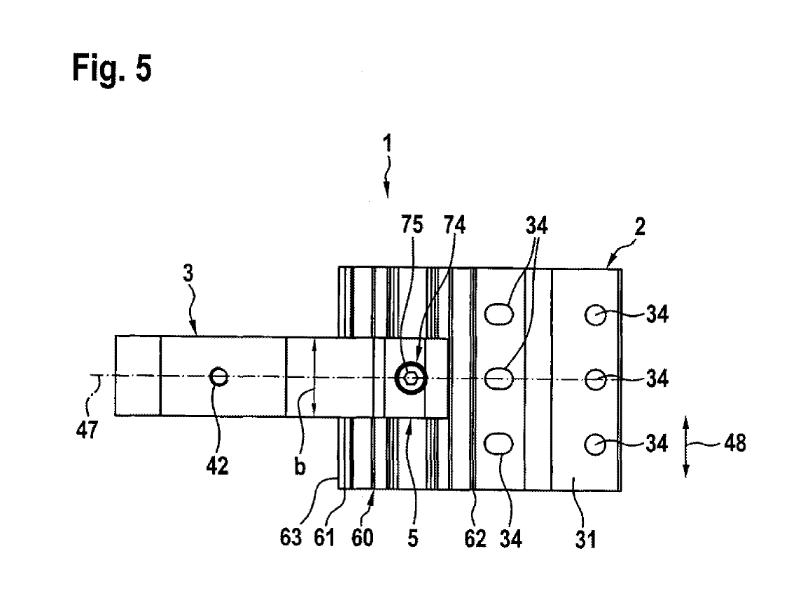

FIG. 5 shows a top view of the solar module bracket of FIG. 3,

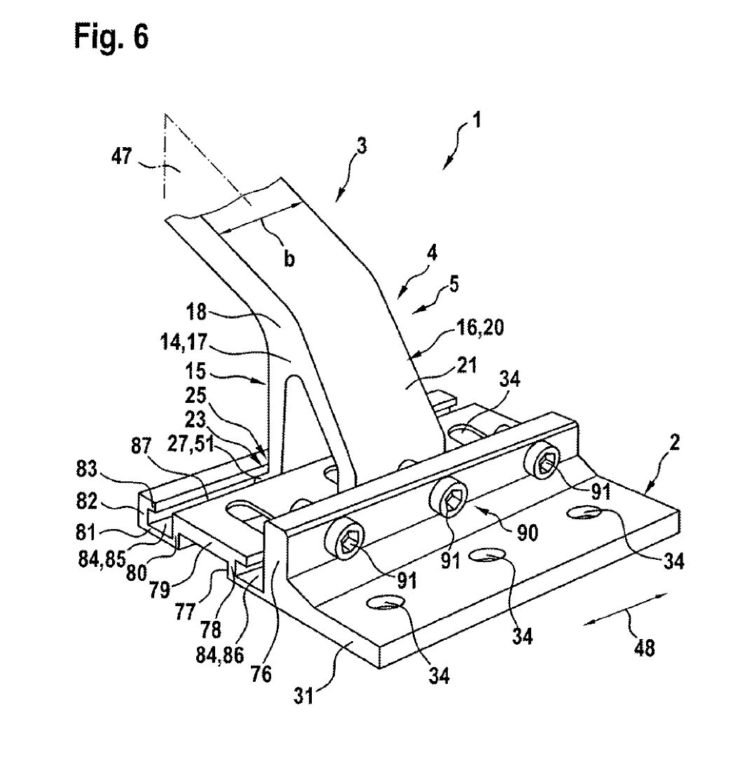

FIG. 6 shows a perspective view of a part shown solar module bracket according to a third exemplary embodiment,

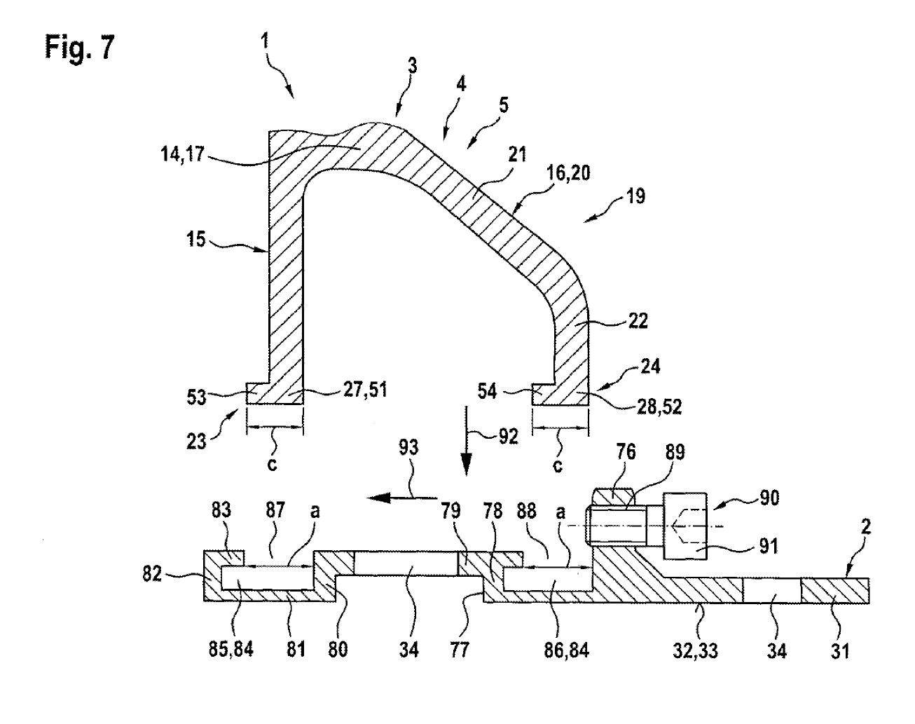

FIG. 7 shows a cross section though the solar module bracket of FIG. 6,

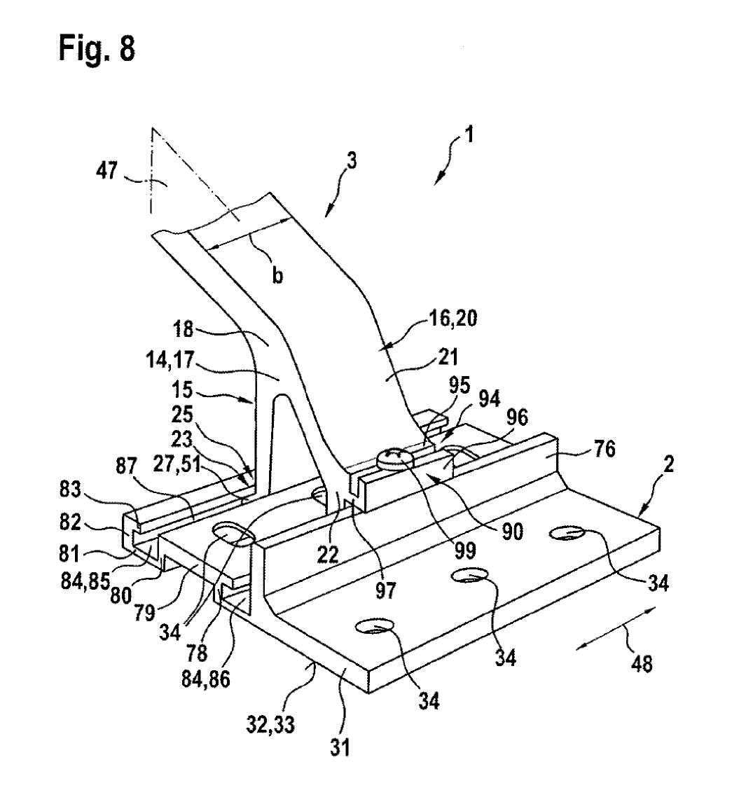

FIG. 8 shows a perspective view of a part shown solar module bracket according to a fourth exemplary embodiment, and

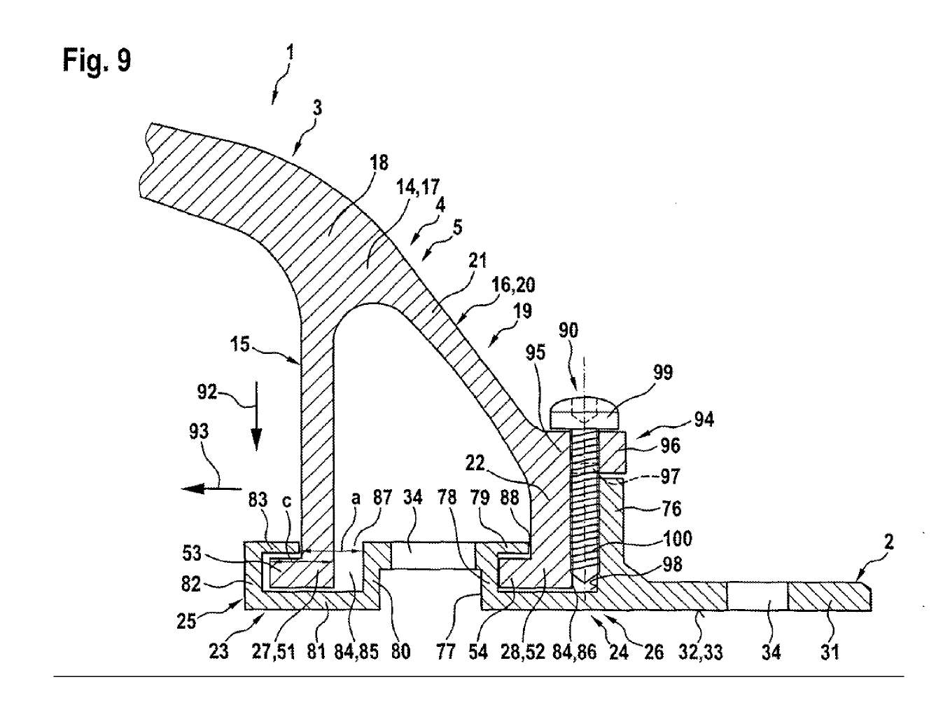

FIG. 9 shows a cross section through the solar module bracket of FIG. 8.

FIG. 1 shows a solar module bracket 1 according to a first exemplary embodiment which comprises a base support 2 and a yoke support 3. The yoke support 3 comprises a fastening region 4, by way of which it is fastened releasably on the base support 2. The fastening region 4 is associated with a first end region 5 of the yoke support 3. The yoke support 3 comprises a second end region 6 which forms a module holding region 7. The module holding region 7 has a clamping holder 8 (FIG. 2) for a module support rail 9. The clamping holder 8 has a first clamping holder part 10 which is only shown in FIG. 2 and not, however, in FIG. 1. A second clamping holder part 11 which is associated with the clamping holder 8 is formed by an end piece 12 of the yoke support 3.

The yoke support 3 has a yoke center region 13 which is developed in a substantially U-shaped manner and which serves the purpose of engaging around a roof covering, for example a roof tile, in such a manner that the fastening region 4 lies below the roof covering and the module holding region 7 lies above the roof covering. The fastening region 4 comprises a branching region 14 from which two arms 15 and 16 proceed. The branching region is developed in a V-shaped manner, therefore forms a V-branching region 17. The branching region 14 is integrally connected to a bending 18 of the yoke center region 13. The arms 15 and 16 are also connected integrally to the branching region 14 and consequently also to the bending 18 and to the yoke center region 13. The arms 15 and 16 form a yoke portion 19 of the yoke support 3. The arm 15 comprises a straight-lined development, i.e. it extends in a straight line between the branching region 14 and the base support 2. The arm 16 is realized as an angled arm 20 which has an arm part 21 and an arm portion 22 which enclose an obtuse angle. The arm portion 22 extends parallel to the longitudinal extension of the arm 15. The arm part 21 encloses an acute angle with the arm 15.

The free ends 23 and 24 of the arms 15 and 16 are releasably connected to the base support 2 by means of slot nuts 25 and 26. The slot nut connections 25 and 26 comprise slot nuts 27 and 28 which are connected integrally to the arms 15 and 16 and are pushed into receiving grooves 29 and 30 of the base support 2. The receiving grooves 29 and 30 are developed as C-profile grooves. In particular, they are realized as push-in receiving grooves 73. The pushing in is effected in the direction of the longitudinal extension of the push-in receiving grooves 73. The slot nuts 27 and 28 are realized as T-slot nuts 101 and 102.

The base support 2 is realized as a base plate 31. The underside 32 of the base plate 31 forms a fastening plane 33. The two receiving grooves 29 and 30 extend parallel to one another and extend over the entire width of the base plate 31 such that it is possible to push the slot nuts 27 and 28 of the arms 15 and 16 in at the side. For fastening the base support 2 or the base plate 31, said base support or base plate comprises several fastening holes 34, the arrangement being in such a manner that several fastening holes 34 lie between the receiving grooves 29 and 30 and consequently between the arms 15 and 16. The fastening holes 34 which are situated between the receiving grooves 29 and 30 are realized in a preferred manner as elongated holes. The remaining fastening holes 34 are developed as circular holes and are arranged in rows, the fastening holes 34 which are developed as elongated holes also being arranged in rows with respect to one another, the two rows of holes extending parallel to one another and parallel to the receiving grooves 29, 30. With regard to the fastening holes 34 which are realized as elongated holes, it must be mentioned that only two fastening holes 34 can be seen in FIG. 1. However, there is also a third fastening hole 34 which is covered by the arm 16 and is located centrally between the two that are visible. The receiving groove 29 extends along a side edge of the base plate 31. The receiving groove 30 extends approximately in the center of the base plate 31. The circular fastening holes 34 are situated in the vicinity of the side edge 36 which is located opposite the side edge 35.

The first clamping holder part 10 is realized as an angle bracket 37 and has a first leg 38 and a second leg 39 which is arranged at an angle with respect to said first leg. The leg 38 comprises a fastening hole 40 which is passed through by a clamping screw 41 which is screwed into a threaded bore 42 of the yoke support 3. The angle bracket 37 comprises a clamping hook 43 which interacts with a retaining hook 44 of the module support rail 9 which is H-shaped in cross section. When the clamping screw 41 is tightened, the angle bracket 37 is moved in the direction of the yoke support 3, as a result of which the clamping hook 43 tensions the retaining hook 44 in the direction of the end piece 12, as a result of which the module support rail 9, which is supported on the top surface 45 of the end piece 12 and preferably also on a side wall 46 of the angle bracket 37, is secured.

Several solar module brackets 1, which are all connected to the same module support rail 9, are preferably arranged on the roof spaced apart from one another. One solar module bracket or several solar module brackets can then be fastened on the module support rail 9.

According to FIG. 1, the solar module bracket 1 or the yoke support 3 comprises a yoke center plane 47. The sectional representation in FIG. 2 lies in said yoke center plane 47. It can be seen that the fastening plane 33, which is formed by the underside 32 of the base plate 31, is oriented perpendicularly on the yoke center plane 47, the longitudinal extensions of the receiving grooves 29 and 30 (arrow 48) extending parallel to the fastening plane 33 and lying perpendicular to the yoke center plane 47.

It can be seen in FIGS. 1 and 2 that the two arms 15 and 16 lie in the yoke center plane 47. The yoke support 3 comprises a yoke width b which is the same size overall, that is constant, both in the region of the end piece 12, in the yoke center region 13, in the region of the bending 18, in the branching region 14 and in the arms 15 and 16 and also in the regions of the slot nuts 27 and 28 such that the latter extend over the entire yoke width b. It can be seen in FIG. 1 that the width of the base plate 31 is greater than the width of the yoke support 3 such that the yoke support 3 is able to be displaced along the longitudinal extension of the receiving grooves 29 and 30 (arrow 48). Regarding the integrality of the yoke support 3, it must also be said that that the yoke center region 13 merges integrally into the second end region 6 and consequently also into the end piece 12.

When assembling the solar module bracket 1 according to the invention, the procedure is as follows: First of all, the base support 2 is fastened on the roof, in particular on a rafter, a purlin and/or a batten, by at least one fastening means being screwed into a fastening hole 34 of the row of holes lying between the arms 15 and 16. In addition, at least one further fastening means can be inserted into one of the other fastening holes 34, in particular a fastening hole 34 of the other row of holes. The yoke support 3 is then assigned to the base support 2 by the slot nuts 27 and 28 being inserted into the receiving grooves 29 and 30, care being taken to ensure that the yoke center region 13 engages around a roof covering, for example a roof tile. As a result, the module holding region 7 comes to lie above the roof tile such that the module support rail 9 is able to be held there as a result of clamping. At least one solar module bracket is then fastened on the module support rail 9.

FIGS. 3 to 5 show a solar module bracket 1 according to a second exemplary embodiment. Said solar module bracket 1 is realized in a similar manner to the solar module bracket 1 according to the first exemplary embodiment such that, in this respect, reference is made to the description concerning FIGS. 1 and 2 and purely the differences will be discussed below. The clamping bracket 8 is certainly not shown in FIGS. 3 to 5, but the clamping bracket 8 is naturally also provided here—as is shown in FIG. 2.

The arm 15 comprises a substantially straight-lined development, that is it extends in a straight line between the branching region 14 and the base support 2. It comprises a curvature purely in the vicinity of the branching region 14. The arm 16 comprises—proceeding from the branching region 14—a curved arm portion 49 and an arm portion 50 which extends in a straight line and connects thereto. The lineally extending arm portion 50 of the arm 16 extends parallel to the lineal region of the arm 15. The slot nuts 27 and 28 (FIG. 4), which are provided on the free ends 23 and 24 of the arms 15 and 16, are realized as L-slot nuts 51 and 52. The L-slot nuts 51 and 52 comprise in each case a slot nut web 53, 54 which proceeds in a perpendicular manner from the respective arm 15, 16, the slot nut webs 53 and 54 projecting away from the arms 15 and 16 in opposite directions and pointing away from one another. A connecting web 55, which connects the arms 15 and 16 and is realized integrally with the arms 15 and 16, is provided between the arms 15 and 16. The connecting web 55 is provided approximately half way up the arms 15 and 16. The connecting web 55 comprises on its underside 56, which faces the free ends 23 and 24 of the arms 15 and 16, two longitudinal notches 57 and 57′ which extend in a parallel manner. In each case one side of the longitudinal notches 57 and 57′ is defined by the arms 15, 16. A threaded bore 58 is additionally provided in the connecting web 55. The threaded bore 58 is provided in particular centrally in the connecting web 55. An opening 59 is provided in the arm 16, in the curved arm portion 49 thereof. The opening 59 is in alignment with the threaded bore 58.

The base support 2 comprises a base plate 31. A holder 60 is provided on the base plate 31. The holder 60 comprises two longitudinal walls 61 and 62 which project away from the base plate 31 at a right angle and extend in a parallel manner. The one longitudinal wall 61 is arranged on a longitudinal edge 63 of the base plate 31 and the other longitudinal wall 62 is arranged approximately centrally on the base plate 31. Three cross walls 64 project in each case away from the longitudinal walls 61 and 62 in a perpendicular manner. The cross walls 64 project away from the respective longitudinal wall 61, 62 in the direction of the other longitudinal wall 62, 61. The distance between the base plate and the next cross wall 64 and the distance between adjacent cross walls 64 and a longitudinal wall 61, 62 is always the same size. A support strut 65 of the base support 2 is arranged on the base plate 31 between the longitudinal walls 61 and 62. The support strut 65 comprises two side walls 66 and 67, which project away from the base plate 31 in a perpendicular manner and extend parallel to the longitudinal walls 61 and 62, and one cover wall 68 which connects the side walls 66 and 67 at their free ends. Two longitudinal projections 70 and 71, which extend parallel to one another and are able to engage in longitudinal notches 57 and 57′ of the connecting web 55, are realized on the top side 69 of the cover wall 68 in the edge regions thereof.

Receiving grooves 72 and 72′, which are realized as push-in receiving grooves 73, are defined by the base plate 31, the longitudinal walls 61 and 62 and the cross walls 64. Each longitudinal wall 61 or 62 has associated therewith therefore three receiving grooves 72 or 72′ which are at different height distances from the base plate 31. A space is realized in each case between the free ends of the cross walls 64 and the side walls 66 and 67 of the support strut 65. The receiving grooves 72 and 72′ and the spaces are dimensioned in such a manner that the L-slot nuts 51 and 52 are able to engage in each case in one of the receiving grooves 72, 72′ and that the L-slot nuts 51 and 52 are held in the respective receiving groove 72, 72′ and the arms 15 and 16 in the spaces so as to be displaceable (in the direction of the longitudinal extension of the receiving grooves 72 and 72′).

In addition, a clamping safety device 74 is provided. The clamping safety device 74 comprises a clamping screw 75 which—in the mounted state of the solar module bracket 1 according to FIG. 4—passes through the opening 59 provided in the arm 16 and is screwed into the threaded bore 58 of the connecting web 55 and is supported on the cover wall 68.

The fastening holes 34 are provided in the base plate 31 outside the holder 60, that is outside the region lying between the longitudinal walls 61 and 62. In this case, in each case three fastening holes 34 form a row of holes which extends parallel to the longitudinal extension (arrow 48) of the receiving grooves 72 and 72′. In this case, the fastening holes 34 of the one row of holes are realized as circular holes and the fastening holes 34 of the other row of holes are realized as elongated holes. The longitudinal axis of the elongated holes extends transversely, in particular in a perpendicular manner, with respect to the receiving grooves 72 and 72′.

With regard to the assembly of the solar module bracket 1 according to FIGS. 3 to 5, reference is made to the procedure described for FIGS. 1 and 2. Deviating from this, in the case of the assignment of the yoke support 3 to the base support 2 the slot nuts 27 and 28 are in each case pushed into a receiving groove 72, 72′. In this case,—in dependence on the conditions on the roof—two suitable receiving grooves 72 and 72′ are chosen at a certain vertical spacing from the base plate 31 such that the yoke support 3 is able to engage around the roof covering. FIG. 3 shows the solar module bracket 1 in a position in which the slot nuts 27 and 28 are arranged in the two topmost receiving grooves 72 and 72′; FIG. 4 shows the solar module bracket 1 in a position in which the slot nuts 27 and 28 are arranged in the two bottommost receiving grooves 72 and 72′. The yoke support 3 is then displaced along the push-in direction (arrow 48) up to a desired position. In said position, it is secured by means of the clamping screw 75 by the clamping screw 75, which has preferably already been screwed in part into the threaded bore 58 of the connecting web 55, being screwed in further such that the end of the clamping screw 75 is pressed against the cover wall 68 of the support strut 65. As a result, a force acting in the direction of the longitudinal extension of the clamping screw 75 is exerted onto the arms 15 and 16 such that the slot nuts 27 and 28 are held in a force-fitting manner in the associated receiving grooves 72 and 72′ or are wedged in said receiving grooves.

FIGS. 6 and 7 show a solar module bracket 1 according to a third exemplary embodiment. FIG. 6 shows the solar module bracket 1 in the disassembled state and FIG. 7 in the mounted state. In this case, in each case just the base support 2 and a region of the yoke support 3, in particular the fastening region 4 thereof, can be seen. The solar module bracket 1 according to FIGS. 6 and 7 is realized substantially according to FIGS. 1 and 2 such that reference is made to said figures and the corresponding description and purely the differences will be explained below.

Similarly to the case of the second exemplary embodiment, the slot nuts 27 and 28 of the arms 15 and 16 are realized as L-slot nuts 51 and 52 by, in each case, a slot nut web 53, 54 projecting in a perpendicular manner away from the associated arm 15, 16. In this case, the slot nut webs 53 and 54 project away in the same direction.

The base support 2 comprises a base plate 31. A longitudinal web 76 which projects away from said base plate in a perpendicular manner is provided on the base plate 31. A strut 78 projects away parallel to the longitudinal web 76 on a side edge 77 of the base plate 31. An intermediate plate 79, which extends in regions parallel to the base plate 31 and in regions in parallel elongation with respect to the base plate 31, connects to said strut 78. By means of a strut 80 which extends in a perpendicular manner with respect to the intermediate plate 79, said intermediate plate 79 connects to a base plate extension 81, which extends in the plane of the base plate 31 and consequently with the base plate 31 spans the fastening plane 33. The base plate extension 81 merges by means of a strut 82, which projects in a perpendicular manner away from said base plate extension, into a web 83 which extends parallel to the base plate extension 81. The web 83 and the intermediate plate 79 lie in one plane. A receiving groove 85 or 86, which is realized as a hook-in receiving groove 84, is defined in each case by the intermediate plate 79, the strut 80, the base plate extension 81, the strut 82 and the web 83 or by the longitudinal web 76, the base plate 31, the strut 78 and the intermediate plate 79. The receiving grooves 85 and 86 comprise in each case a longitudinal opening 87, 88 which is realized between the web 83 and the intermediate plate 79 or the intermediate plate 79 and the longitudinal web 76. The width a of the longitudinal openings 87 and 88 is greater than the width c of the L-slot nuts 51 and 52.

Three threaded bores 89 are provided in the longitudinal web 76 of the base support 2. The longitudinal axis of the threaded bores 89 extends parallel to the base plate 31. The distance between adjacent threaded screws is preferably smaller than the yoke width b of the yoke support 3. In each case a clamping screw 91 is screwed into the threaded bores 89. In the mounted state of the solar module bracket 1 (FIG. 6) one of the clamping screws 91 is supported by way of its free end on the arm 16, in particular on the arm portion 22 thereof. The threaded bores 89 and the clamping screws 91 form a clamping safety device 90.

The base support 2 comprises six fastening holes 34. Three of the fastening holes 34 are realized as elongated holes and are provided in the intermediate plate 79. The longitudinal axis of the longitudinal holes extends transversely, in particular in a perpendicular manner, with respect to the receiving grooves 85 and 86. The three further fastening holes 34 are provided in the base plate 31 at a spacing from the receiving groove 86 and are realized as circular holes.

When the solar module bracket 1 is mounted, after fastening the base support 2 on the roof the slot nuts 27 and 28 are inserted through the longitudinal openings 87 and 88 into the receiving grooves 85 and 86 along the direction marked by the arrow 92. The slot nuts 27 and 28 are then displaced in the direction of the arrow 93 in the respective receiving groove 85, 86 such that a tongue and groove system is achieved. The yoke support 3 can also be displaced in the direction of the longitudinal extension of the receiving grooves 85 and 86 (arrow 48) in order to set a desired position of the yoke support 1 relative to the base support 2 and consequently to the roof. Said position is then secured by means of one of the clamping screws 91 by the clamping screw 91 being screwed further into the threaded bore 89 and as a result being pressed by way of its free end against the arm 16.

The fourth exemplary embodiment according to FIGS. 8 and 9 corresponds substantially to the exemplary embodiment of FIGS. 6 and 7 such that in this respect reference is made to the description concerning FIGS. 6 and 7 and purely the differences to FIGS. 6 and 7 will be explained below.

A U-shaped U-holder 94 which extends over the yoke width b is provided on the arm 16 of the yoke support 3 on the transition region thereof from the arm part 21 into the arm portion 22. The U-holder comprises two legs 95 and 96 and one base 97 which connects the legs 95 and 96. The one leg is realized integrally with the arm 16. An opening (not visible) is provided in the base 97.

A side of the longitudinal web 76 of the base support and a side of the arm portion 22 of the arm 16 located opposite said side form a screw channel 98 for a locating screw 99 of the clamping safety device 90. The locating screw 99—in the mounted state of the solar module bracket 1—passes through the opening of the base 97 and is screwed into the screw channel 98 by way of its thread 100. The screw channel 98 can be formed by a toothing which is provided on the opposite sides of the arm portion 22 and of the longitudinal web 76, or as a result of screwing in the locating screw 99 which in the latter case is realized as a self-tapping locating screw.

The mounting of the solar module bracket 1 of FIGS. 8 and 9 is effected substantially according to the mounting of the solar module bracket 1 according to FIGS. 6 and 7. The locating screw 99 is preferably initially screwed by way of its thread 100 between the legs 95 and 96 such that it is held in a captive manner on the yoke support 3 and consequently is able to be screwed into the screw channel 98 for securing once the yoke support 3 has been positioned on the base support 2.

1. A solar module bracket (1) having a base support (2) which is fastenable in particular on a roof and a yoke support (3) for holding a module support rail (9), wherein the yoke support (3) comprises a fastening region (4) which is releasably connected to the base support (2), characterized in that the fastening region (4) is formed by a yoke portion (19) of the yoke support (3) which comprises several arms (15, 16), wherein each arm (15, 16) of the yoke portion (19) is releasably connected to the base support (2).

2. The solar module bracket as claimed in claim 1, characterized in that the fastening region (4) is associated with a first end region (5) of the yoke support (3).

3. The solar module bracket as claimed in one of the preceding claims, characterized in that the yoke support (3) comprises a yoke center region (13) which merges integrally into a branching region (14) which, in turn, merges integrally into the arms (15, 16).

4. The solar module bracket as claimed in one of the preceding claims, characterized by two arms (15, 16) and the realization of the branching region (14) as a V-shaped branching region (17).

5. The solar module bracket as claimed in one of the preceding claims, characterized in that the longitudinal extensions of the arms (15, 16) enclose at least in portions an acute angle.

6. The solar module bracket as claimed in one of the preceding claims, characterized in that at least one of the arms (15, 16) is an angled arm (20).

7. The solar module bracket as claimed in one of the preceding claims, characterized in that free ends (23, 24) of the arms (15, 16) are connected to the base support (2) by means of slot nut connections (25, 26).

8. The solar module bracket as claimed in one of the preceding claims, characterized in that the base support (2) is realized as a base plate (31) or comprises a base plate (31).

9. The solar module bracket as claimed in one of the preceding claims, characterized in that the base support (2) comprises at least one fastening hole (34) which lies between the arms (15, 16) or outside a region of the base support (2) which lies between the arms (15, 16).

10. The solar module bracket as claimed in one of the preceding claims, characterized in that the yoke support (3) spans a yoke center plane (47), wherein the arms (15, 16) lie in the yoke center plane (47).

11. The solar module bracket as claimed in one of the preceding claims, characterized in that the yoke support (3) comprises a yoke width (b) which is constant or approximately constant over the entire longitudinal development of the yoke support.

12. The solar module bracket as claimed in one of the preceding claims, characterized in that the yoke support (3) comprises a module holding region (7) which forms a second end region (6) of the yoke support (3).

13. The solar module bracket as claimed in one of the preceding claims, characterized in that the module holding region (7) comprises a clamping holder (8) for the module support rail (9).

14. The solar module bracket as claimed in one of the preceding claims, characterized in that at least one of the arms (15, 16) extends in a straight line and is oriented in a perpendicular manner with respect to the plane of the base plate (31).

15. The solar module bracket as claimed in one of the preceding claims, characterized in that the angled arm (20) comprises an arm portion (22) which is oriented in a perpendicular manner with respect to the plane of the base plate (31).

16. The solar module bracket as claimed in one of the preceding claims, characterized in that the arm portion (22) is connected to the base support (2) by means of one of the slot nut connections (25, 26).

17. The solar module bracket as claimed in one of the preceding claims, characterized in that the yoke center region (13) comprises a bending (18) to which the branching region (14) connects in a direct manner.

18. The solar module bracket as claimed in one of the preceding claims, characterized in that the slot nut connections (25, 26) are realized as displacing connections.

19. The solar module bracket as claimed in one of the preceding claims, characterized in that the slot nut connections (25, 26) comprises in each case a slot nut (27, 28) which is provided on the free end (23, 24) of the respective arm (15, 16) and at least one receiving groove (29, 30, 72, 72′, 85, 86) which is provided on the base support (2) for the slot nut (27, 28).

20. The solar module bracket as claimed in one of the preceding claims, characterized in that receiving groove (29, 30, 72, 72′, 85, 86) comprises a longitudinal extension (arrow 48) along which the slot nut (27, 28) is arranged so as to be pushable into the receiving groove (29, 30, 72, 72′, 85, 86) and displaceable in the receiving groove (29, 30, 72, 72′, 85, 86).

21. The solar module bracket as claimed in one of the preceding claims, characterized in that the slot nut (27, 28) is realized as an L-slot nut (51, 52) or a T-slot nut (101, 102).

22. The solar module bracket as claimed in one of the preceding claims, characterized in that the receiving groove (29, 30, 72, 72′, 85, 86) is realized as an push-in receiving groove (73) or a hook-in receiving groove (84).

23. The solar module bracket as claimed in one of the preceding claims, characterized in that several receiving grooves (29, 30, 72, 72′, 85, 86), which are at different height intervals from the plane of the base plate (31), are provided on the base support (2) for each slot nut (27, 28).

24. The solar module bracket as claimed in one of the preceding claims, characterized in that the several receiving grooves (29, 30, 72, 72′, 85, 86) are provided arranged one above another on a holder (60) which is provided on the base plate (31).

25. The solar module bracket as claimed in one of the preceding claims, characterized in that the holder (60) comprises two longitudinal walls (61, 62), which project away from the base plate (31) in a perpendicular manner and are parallel to one another, with in each case several cross walls (64), wherein the receiving grooves (29, 30, 72, 72′, 85, 86) are realized between the base plate (31) and two of the cross walls (64) as well as between the further cross walls (64).

26. The solar module bracket as claimed in one of the preceding claims, characterized in that a support strut (65), which is associated with the base support (2), for the arms (15, 16) is arranged between the longitudinal walls (61, 62).

27. The solar module bracket as claimed in one of the preceding claims, characterized by at least one clamping safety device (74, 90) for effectively securing the relative position of the yoke support (3) and the base support (2) with respect to one another in particular in the direction of the longitudinal extensions of the receiving grooves (29, 30, 72, 72′, 85, 86).

28. The solar module bracket as claimed in one of the preceding claims, characterized in that the clamping safety device (74, 90) comprises at least one clamping screw (91) which is screwed into a threaded bore (89) of the base support (2) and is supported on the yoke support (3) and/or at least one clamping screw (75) which is screwed into a threaded bore (58) of the yoke support (3) and is supported on the base support (2).

29. The solar module bracket as claimed in one of the preceding claims, characterized in that the clamping safety device (74, 90) comprises at least one locating screw (99) which, by way of its thread (100), is screwed into a screw channel (98) which is realized between an arm (15, 16) and a longitudinal web (76) of the base support (2) which proceeds from the base plate (31) and defines at least one of the receiving grooves (29, 30, 72, 72′, 85, 86) in regions.
